(19) United States
(12) Patent Application Publication
(10) Pub. No.: US 2026/0223540 A1
(43) Pub. Date: Jul. 30, 2026

(54) DISPLAY APPARATUS AND LARGE-AREA DISPLAY PANEL

(71) Applicant: LG Display Co., Ltd., Seoul (KR)

(72) Inventors: Taeryong KIM, Paju-si (KR); Changheon KANG, Paju-si (KR); Donghyun YEO, Paju-si (KR); Soonsung AHN, Paju-si (KR)

(21) Appl. No.: 19/436,198

(22) Filed: Dec. 30, 2025

(30) Foreign Application Priority Data
Jan. 24, 2025 (KR) 10-2025-0011219

(51) Int. Cl. H10K 59/121; G09G 3/3266; H10K 59/131; H10K 59/18

(52) U.S. Cl. CPC H10K 59/1213; G09G 3/3266; H10K 59/131; H10K 59/18; G09G 2300/026; G09G 2330/021; G09G 2330/06

(57) ABSTRACT

A display apparatus including an active area in which a plurality of pixels are disposed, and non-active areas arranged on both sides of the active area in a horizontal direction, in which: in each of the non-active areas, an electro-static discharge (ESD) circuit and a gate-in-panel (GIP) circuit are disposed, and in the active area, the pixels include a thin film transistor to which oxide has been applied, and semiconductor elements to which low temperature polycrystalline silicon (LTPS) has been applied are disposed.

### CROSS REFERENCE TO RELATED APPLICATION

This application claims priority from and the benefit of Korean Patent Application No. 10-2025-0011219, filed on January 24, 2025, which is hereby incorporated by reference for all purposes as if fully set forth herein.

### BACKGROUND

### FIELD

Embodiments of the invention relate generally to a display apparatus.

### DISCUSSION OF THE BACKGROUND

An organic light-emitting display apparatus is a self-emitting type display apparatus, and thus, unlike a liquid crystal display apparatus, requires no separate light source, thereby enabling a lightweight and thin structure. In addition, the organic light-emitting display apparatus is not only advantageous in terms of power consumption by low voltage driving, but also has excellent color implementation, response speed, viewing angle, and contrast ratio (CR), and thus has been studied as a next-generation display.

Display apparatuses are constantly being improved to provide users with clearer images by increasing the resolution and luminance of the screen.

The pixels of the organic light-emitting display panel may include a driving transistor and switch transistors, and both the driving transistor and the switch transistors may be implemented as oxide thin film transistors. The pixel to which the oxide thin film transistor has been applied may realize low power consumption due to low off-current characteristics. The pixel to which the oxide thin film transistor has been applied may be manufactured without applying an excimer laser annealing (ELA) process through which a-Si (amorphous silicon) is converted into poly-Si (polysilicon). On the other hand, the GIP (Gate-In-Panel) circuit requires a device whose operating speed is relatively greater than that of the pixel area, so the circuit should be designed with a low temperature polycrystalline silicon (LTPS) thin film transistor having high mobility. Additionally, since the electro-static discharge (ESD) circuit protecting the pixel must have robust reliability, the stability of the circuit must be ensured by using LTPS thin film transistors.

However, the conventional display apparatus has an ESD circuit at the lower end portion of the display panel, so there is a disadvantage that the ELA process must be carried out over the entire area of the display panel to produce the same ESD circuit as the conventional design. Additionally, when manufacturing organic light-emitting display panels on large-area substrates, conventional display apparatuses have a problem of increasing tact time due to ELA process characteristics, and have a problem of lowering the required equipment panel production capacity and production efficiency.

The above information disclosed in this Background section is only for understanding of the background of the inventive concepts, and, therefore, it may contain information that does not constitute prior art.

### SUMMARY

A display apparatus according to embodiments of the invention is capable of realizing low power consumption and maintaining characteristics of LTPS with robust reliability by disposing the ESD circuit in the ELA crystallized area where the GIP circuit is disposed.

A display apparatus according to embodiments of the invention is capable of realizing low power consumption and maintaining the characteristics of LTPS with robust reliability, by disposing pixels, to which oxide thin film transistors have been applied, in a pixel area, and disposing an ESD circuit, to which LTPS thin film transistors have been applied, in an area in which GIP circuits are disposed.

A large-area display panel according to embodiments of the invention is capable of maintaining the ELA process application to a partial area, by applying oxide thin film transistors to an active area where a plurality of pixels are placed, and applying LTPS thin film transistors to non-active areas on both sides of the active area in a horizontal direction, in each of which an ESD circuit and GIP circuits are disposed, when manufacturing the large-area display panel.

Additional features of the inventive concepts will be set forth in the description which follows, and in part will be apparent from the description, or may be learned by practice of the inventive concepts.

According to one or more embodiments of the invention, a display apparatus includes an active area in which a plurality of pixels are disposed; and non-active areas on both sides of the active area in a horizontal direction, in each of the non-active areas an electro-static discharge (ESD) circuit and a gate-in-panel (GIP) circuit are disposed, the pixels disposed in the active area have a thin film transistor to which oxide has been applied, and in the non-active area, semiconductor elements, to which low temperature polycrystalline silicon (LTPS) has been applied, are disposed.

The non-active area may be defined as an area to which an excimer laser annealing (ELA) process of converting amorphous silicon (a-Si) into poly-Si has been applied, and the active area may be defined as an area to which no ELA process has been applied.

The ESD circuit in the non-active area may be electrically connected with a data line in the active area through a sub-data line.

The sub-data line may extend in the horizontal direction from the data line in the active area to the ESD circuit in the non-active area.

In the non-active area in which the ESD circuit is disposed, a first voltage line transmitting a gate high voltage, and a second voltage line transmitting a gate low voltage may be further disposed.

The ESD circuit may include a first thin film transistor having a first electrode electrically connected to the sub-data line, a second electrode electrically connected to the first voltage line, and a gate electrode electrically connected to the first voltage line; and a second thin film transistor having a first electrode electrically connected to the sub-data line, a second electrode electrically connected to the second voltage line, and a gate electrode electrically connected to the sub-data line.

The first thin film transistor and the second thin film transistor may be p-type LTPS-thin film transistors.

The pixels may include a driving transistor and at least one switch transistor, and both the driving transistor and the at least one switch transistor may be oxide thin film transistors.

The GIP circuit may include at least one LTPS-thin film transistor.

The GIP circuit in the non-active may be electrically connected with the pixels in the active area through gate lines.

According to yet another embodiment of the invention, a large-area display panel includes a large-area substrate on which a plurality of display panels are arranged in a matrix. Each of the plurality of display panels includes: an active area in which a plurality of pixels are disposed; and non-active areas on both sides of the active area in a horizontal direction, in each of the non-active areas an electro-static discharge (ESD) circuit and a gate-in-panel (GIP) circuit are disposed. The plurality of pixels in the active area include a thin film transistor to which oxide has been applied, and the ESD circuit and the GIP circuit in the non-active area include a thin film transistor to which low temperature poly silicon (LTPS) has been applied.

The ESD circuit and the GIP circuit in the non-active area may include at least one or more transistors, and all of the at least one or more transistors may be LTPS thin film transistors.

In the active area, a gate line configured to transmit a gate signal may be disposed, and the GIP circuit in the non-active area may be electrically connected with the pixels in the active area through the gate line.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a block diagram schematically illustrating an organic light-emitting display apparatus according to an embodiment of the invention.

FIG. 2 is a plan view illustrating a large-area display panel according to an embodiment of the invention.

FIG. 3 is an enlarged view of the first area ZA1 of the display panel of FIG. 2.

FIG. 4 is a cross-sectional view illustrating a stack structure of a pixel area in an organic light-emitting display apparatus according to an embodiment of the invention.

FIG. 5 is a plan view illustrating a first area ZA1 in the display panel of FIG. 2.

FIG. 6 is a cross-sectional view taken along line A-A′ in FIG. 5.

FIG. 7 is an enlarged cross-sectional view of the second area ZA2 of FIG. 6.

FIG. 8 is a cross-sectional view taken along line B-B′ in FIG. 5.

FIG. 9 is an enlarged cross-sectional view of the third area ZA3 of FIG. 8.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

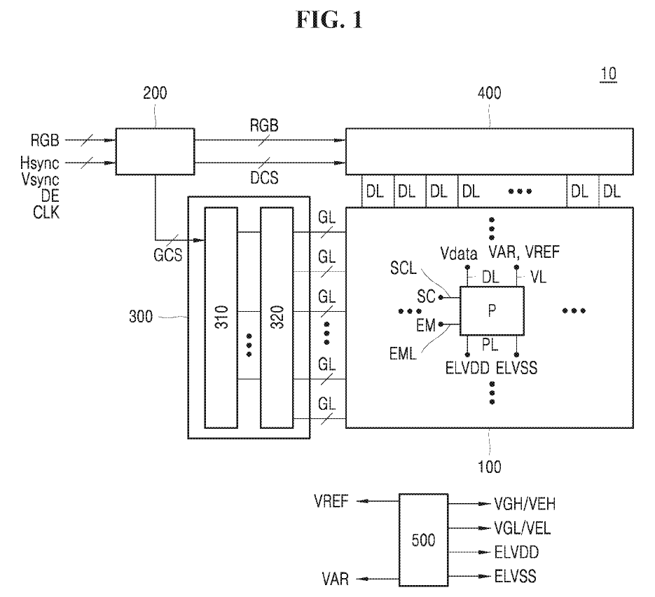

FIG. 1 is a block diagram schematically illustrating an organic light-emitting display apparatus according to an embodiment of the invention.

Referring to FIG. 1, the display apparatus 10 includes a display panel 100 including a plurality of pixels P, a controller 200, a gate driving part 300 that supplies a scan signal SC to the plurality of pixels P, a data driver 400 that supplies a data voltage Vdata to the plurality of pixels P, and a power supply unit 500 that supplies voltages required to drive the plurality of pixels P.

In the display panel 100, a plurality of gate lines GL and a plurality of data lines DL intersect with each other, and each of a plurality of pixels P is electrically connected to a gate line GL and a data line DL. Specifically, one pixel P receives a gate signal from the gate driving part 300 through the gate line GL, receives a data voltage Vdata from the data driver 400 through the data line DL, and receives a high-potential driving voltage ELVDD and a low-potential driving voltage ELVSS from the power supply unit 500.

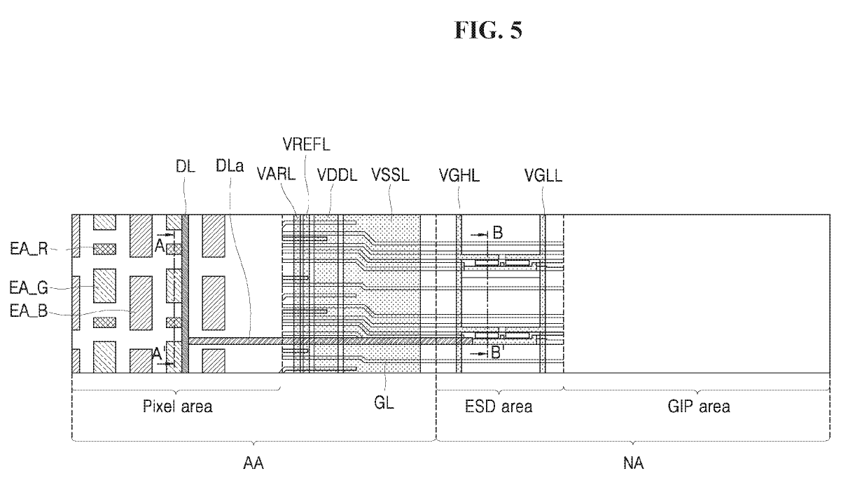

The gate line GL supplies a scan signal SC and an emission control signal EM, and the data line DL supplies a data voltage Vdata. Additionally, according to various embodiments, the gate line GL may include a plurality of scan lines SCL supplying scan signals SC, and an emission control signal line EML supplying an emission control signal EM. Additionally, the plurality of pixels P may further include a power line VL to receive a reference voltage VREF and a reset voltage VAR. The power line VL may include a reference power line VREFL and a reset power line VARL (as shown in FIG. 5). Additionally, the plurality of pixels P may include a power line PL to receive a high-potential driving voltage ELVDD and a low-potential driving voltage ELVSS. The power line PL may include a high-potential power line VDDL and a low-potential power line VSSL (as shown in FIG. 5).

Each pixel P includes a light-emitting element and a pixel circuit. The pixel circuit includes a plurality of switching elements, driving elements, and capacitors. Here, the switching element and the driving element may be configured with a thin film transistor. In the pixel circuit, the driving element controls the amount of current supplied to the light-emitting element according to a data voltage, thereby adjusting the amount of light emitted by the light-emitting element. Additionally, the plurality of switching elements operate the pixel circuit by receiving the scan signals SC supplied through the plurality of scan lines SCL and the emission control signal EM supplied through the emission control signal line EML.

The display panel 100 may be implemented as a non-transmissive display panel or a transmissive display panel. The transmissive display panel may be applied to a transparent display apparatus that displays an image on a screen while allowing a real background object to be visible. The display panel 100 may be manufactured as a flexible display panel. The flexible display panel may be implemented as an OLED panel employing a plastic substrate, without being limited thereto.

On the display panel 100, a plurality of touch sensors may be disposed. Touch input may be sensed using separate touch sensors or through pixels P. The touch sensors may be disposed on the screen of the display panel as “on-cell” type or “add on” type, or be implemented as “in-cell” type touch sensors built in the display panel 100.

The controller 200 processes image data RGB input from a host system to be suitable to the size and resolution of the display panel 100, and supplies the resultant of the processing to the data driver 400. The controller 200 generates a gate control signal GCS and a data control signal DCS by using synchronous signals input from the outside, such as a clock signal CLK, a data enable signal DE, a horizontal synchronous signal Hsync, and a vertical synchronous signal Vsync. By supplying the generated gate control signal GCS and data control signal DCS to the gate driving part 300 and data driver 400, respectively, the controller 200 controls the gate driving part 300 and the data driver 400.

The controller 200 may be configured to be combined with various processors, such as a microprocessor, a mobile processor, an application processor, or the like, depending on the device on which it is mounted.

The host system may be any one of a television (TV) system, a set-top box, a navigation system, a personal computer (PC), a home theater system, a mobile device, a wearable device, or a vehicle system.

The controller 200 generates signals so that the pixels P may be driven at various refresh rates. The refresh rate may be defined as the number of frames transmitted per second. That is, the controller 200 generates signals related to the driving so that the pixels P may be driven at a variable refresh rate when operating in a variable refresh rate mode. For example, the controller 200 may simply change the speed of the clock signal, or generate a synchronization signal to allow a horizontal blank or a vertical blank to be formed.

The controller 200 generates a gate control signal GCS for controlling the operation timing of the gate driving part 300 and a data control signal DSC for controlling the operation timing of the data driver 400 based on the timing signals Vsync, Hsync, and DE received from the host system. The controller 200 synchronizes the gate driving part 300 and the data driver 400 by controlling the operation timing.

The gate driving part 300 supplies a scan signal SC to the gate line GL according to the gate control signal GCS supplied from the controller 200. The gate driving part 300 may be disposed on one or both sides of the display panel 100 in a GIP (Gate-In-Panel ) manner.

In the organic light-emitting display apparatus, the gate driving part 300 supplies a scan signal SC and an emission control signal EM to the display panel 100. The scan signal SC may include a scan pulse that swings between the gate low voltage VGL and the gate high voltage VGH. The emission control signal EM includes an emission control signal pulse that swings between the gate low voltage VEL and the gate high voltage VEH. The scan pulse is synchronized with the data voltage Vdata to be used in selecting a line of pixels P to which data is to be written. The emission control signal pulse defines emission time of the pixels P.

The gate driving part 300 includes at least one emission control signal driver 310 and at least one scan driving part 320. The emission control signal driver 310 outputs a emission control signal pulse in response to a start pulse and shift clock from the controller 200, and sequentially shifts the emission control signal pulse according to the shift clock. The scan driving part 320 outputs a scan pulse in response to the start pulse and shift clock from the controller 200, and shifts the scan pulse according to the shift clock timing.

The data driver 400 converts image data RGB into data voltage Vdata according to a data control signal DCS supplied from the controller 200, and supplies the converted data voltage Vdata to the pixel P through the data line DL.

In FIG. 1, the data driver 400 is illustrated as being disposed on one side of the display panel 100 in one form, but the number and disposition positions of the data drivers 400 are not limited thereto. In some embodiments, the data driver 400 may be configured with a plurality of integrated circuits (ICs), and be disposed on one side of the display panel 100 in multiple separate sections.

The power supply unit 500 uses a DC-DC converter to generate DC power required to drive the pixel array of the display panel 100, the gate driving part 300, and the data driver 400. The DC-DC converter may include a charge pump, a regulator, a buck converter, a boost converter, or the like. The power supply unit 500 may receive a DC input voltage applied from the host system to generate DC voltage, such as gate low voltages VGL and VEL, gate high voltages VGH and VEH, a high-potential driving voltage ELVDD, a low-potential driving voltage ELVSS, a reset voltage VAR, a reference voltage VREF, or the like. The gate low voltages VGL, VEL and the gate high voltages VGH, VEH are supplied to a level shifter and the gate driving part 300. The high-potential driving voltage ELVDD, the low-potential driving voltage ELVSS, the reset voltage VAR, and the reference voltage VREF are supplied to the pixels P.

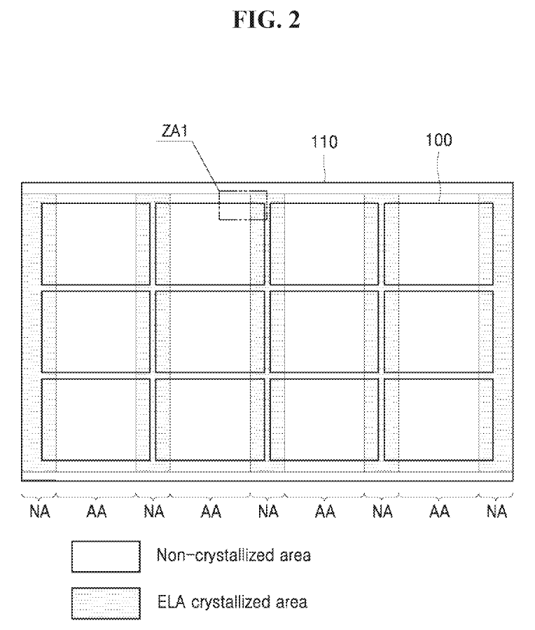

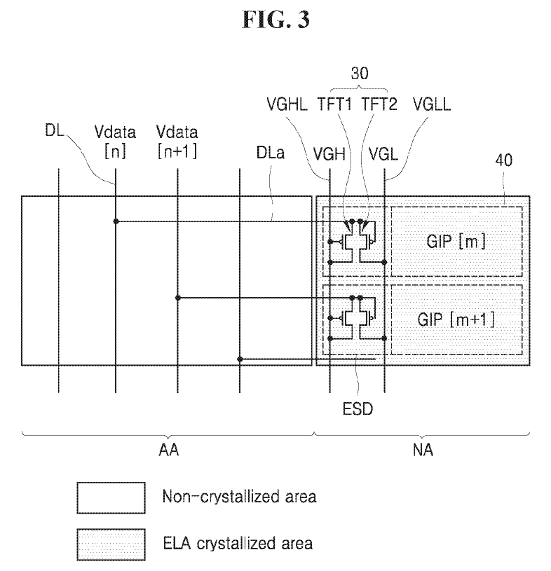

FIG. 2 is a plan view illustrating a large-area display panel according to an embodiment of the invention. FIG. 3 is an enlarged view of the first area ZA1 of the display panel of FIG. 2.

Referring to FIGS. 2 and 3, the large-area display panel includes a large-area substrate 110 and a plurality of display panels 100 disposed on the substrate 110. The substrate 110 may be a glass substrate having a large area. Alternatively, the substrate 110 may be a plastic substrate having a large area.

The large-area substrate 110 may include a plurality of display panels 100 arranged in a matrix. Each of the plurality of display panels 100 may include an active area AA in which a plurality of pixels are disposed, and non-active areas NA in the both sides of the active area AA in a horizontal direction, in each of which an electro-static discharge (ESD) circuit 30 and GIP circuits 40 are disposed.

The plurality of pixels in the active area AA may include a thin film transistor to which an oxide is applied. The ESD circuit 30 and the GIP circuit 40 of the non-active area NA may include a thin film transistor to which low-temperature polycrystalline silicon (LTPS) has been applied. The non-active area may be manufactured by applying an Excimer Laser Annealing (ELA) process that converts amorphous silicon (a-Si) into polycrystalline silicon (Poly-Si) to implement a thin film transistor to which LTPS has been applied. This non-active area NA may be referred to as an “ELA crystallized area” which has been subjected to the ELA process. When each of the thin film transistors of the pixels are formed as oxide thin film transistors, the ELA process may not be performed in the active area. According to an embodiment, the active area may not require the ELA process because all thin film transistors of the pixels therein are formed as oxide thin film transistors. This active area AA may be referred to as a “non-crystallized area” which has been subjected to no ELA process.

In the active area AA, data lines DL may be disposed which transmit a data voltage Vdata. Additionally, sub-data lines DLa may be disposed which extend in the horizontal direction from the data lines DL in the active area AA to the ESD circuit 30 in the non-active area NA.

In the non-active area NA in which the ESD circuit 30 is disposed, there may be disposed a first voltage line VGHL transmitting the gate high voltage VGH and a second voltage line VGLL transmitting the gate low voltage VGL.

To each of the data lines DL, the ESD circuit 30 may be electrically connected through the sub-data lines DLa. The ESD circuit 30 may include a first thin film transistor TFT1 and a second thin film transistor TFT2, which are electrically connected to one data line DL.

The first thin film transistor TFT1 has a first electrode electrically connected to the sub-data line DLa, a second electrode electrically connected to the first voltage line VGHL, and a gate electrode electrically connected to the first voltage line VGHL. The first electrode may be a source electrode or a drain electrode. The second electrode may be a drain or source electrode.

The second thin film transistor TFT2 has a first electrode electrically connected to the sub-data line DLa, a second electrode electrically connected to the second voltage line VGLL, and a gate electrode electrically connected to the sub-data line DLa. Here, the first thin film transistor TFT1 and the second thin film transistor TFT2 may be p-type LTPS-thin film transistors.

The display apparatus 10 may discharge static electricity introduced through the data line DL by disposing the sub-data line DLa to connect the data line DL with the ESD circuit 30. Furthermore, the display apparatus 10 may prevent the elements of the pixel circuit from being damaged by static electricity by discharging the static electricity introduced through the data line DL.

Each pixel of the active area AA may include a storage capacitor, a driving transistor, and at least one switch transistor. Both the driving transistor and the at least one switch transistor may be implemented as oxide thin film transistors. Since the active area AA includes all the transistors of the pixels implemented as oxide thin film transistors, it may be defined as a non-crystallized area that requires no ELA process.

The display apparatus 10 may realize low power consumption by disposing the oxide thin film transistors in the active area AA. Additionally, the display apparatus 10 may maintain the characteristics of LTPS with robust reliability by disposing the ESD circuit 30 and the GIP circuit 40 in the ELA crystallized area.

The display apparatus 10 may realize low power consumption and drive pixels at a high speed by applying the oxide thin film transistors to the active area AA in which multiple pixels are disposed, and applying the LTPS thin film transistors to the non-active area NA in which the ESD circuit 30 and the GIP circuits 40 are disposed.

The display apparatus 10 may maintain the application of the ELA process to the partial area because the ESD circuit 30 and the GIP circuit 40 are implemented by applying LTPS thin film transistors to both sides of the active area AA when manufacturing a large-area display panel. Additionally, when manufacturing a large-area display panel, by maintaining the ELA process in the partial area rather than over the entire area, the display apparatus 10 enables a decrease in the number of process equipment, a reduction of process tact time, and an improvement of production capacity and production efficiency.

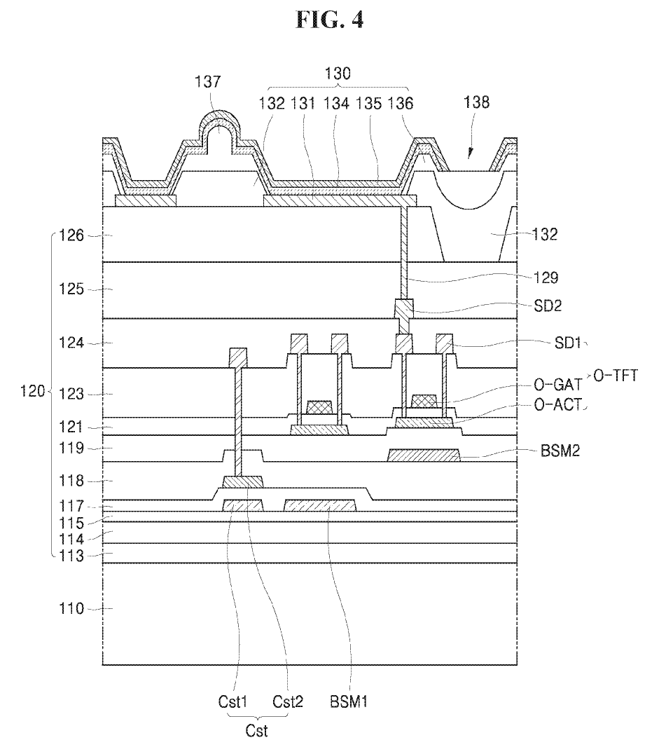

FIG. 4 is a cross-sectional view illustrating a stack structure of a pixel area in an organic light-emitting display apparatus according to an embodiment of the invention.

FIG. 4 illustrates two oxide thin film transistors O-TFT and one storage capacitor Cst. One of the two oxide thin film transistors O-TFT may be used as a switching transistor, and the other may be used as a driving transistor. Both of the oxide thin film transistors O-TFT may include oxide semiconductor material.

In the driving transistor and at least one switching transistor according to an embodiment of the invention, oxide semiconductor is used as an active layer. The thin film transistor in which oxide semiconductor material is used as an active layer has an excellent leakage current blocking effect, and has relatively low manufacturing cost compared to a thin film transistor in which polycrystalline semiconductor material is used as an active layer. Therefore, in order to reduce the power consumption and lower the manufacturing cost, the pixel driving circuit according to an embodiment of the invention includes a driving transistor and at least one switching transistor which use oxide semiconductor material. In an embodiment of the invention, all thin film transistors of the pixel may be implemented using an oxide semiconductor material.

Because a thin film transistor in which polycrystalline semiconductor material is used has a high operating speed and excellent reliability, thin film transistors in which polycrystalline semiconductor material is used may be applied to the ESD circuit 30 and the GIP circuit 40 according to an embodiment of the invention.

Referring to FIG. 4, the organic light-emitting display apparatus may include a substrate 110, a transistor array part 120, and a light-emitting array part 130.

On the substrate 110, the transistor array part 120 may be disposed. The transistor array part 120 may include a plurality of oxide thin film transistors O-TFT, a plurality of scan lines, a plurality of data lines, and a storage capacitor Cst.

On the transistor array part 120, the light-emitting array part 130 may be disposed. In the light-emitting array part 130, a light-emitting element may be disposed which includes an anode electrode 131, a light-emitting layer 134, and a cathode electrode 135. The light-emitting layer 134 may be an organic light-emitting layer including organic material. By applying a driving current to the anode electrode 131 and the cathode electrode 135 disposed in the up and down direction of the light-emitting layer 134, the light-emitting layer 134 may emit light.

On the light-emitting array part 130, an encapsulation part (not shown) may be disposed. Since the organic light-emitting layer includes the organic material, it may be vulnerable to oxygen and moisture. As such, the organic light-emitting layer including the organic material may be sealed by the encapsulation part to prevent the penetration of oxygen or moisture. The encapsulation part may include an inorganic insulating layer or an organic insulating layer which is formed in a multilayer structure.

Referring to FIG. 4, a first buffer layer 113 may be disposed on the substrate 110. The first buffer layer 113 may cover the surface of the substrate 110. For example, the first buffer layer 113 may cover the entire surface of the substrate 110. The first buffer layer 113 may protect the oxide thin film transistors O-TFT and the storage capacitor Cst by suppressing or preventing the penetration of moisture, oxygen, or impurities through the substrate 110.

The first buffer layer 113 may include multiple layers, and on the first buffer layer 113, a second buffer layer 114 may be disposed. The first buffer layer 113 and the second buffer layer 114 may include an inorganic insulating layer including silicon oxide (SiOₓ) or silicon nitride (SiNₓ). For example, at least one of the first buffer layer 113 and the second buffer layer 114 may be formed of multiple layers in which one or more inorganic insulating layers are alternately disposed.

On the second buffer layer 114, a first insulating layer 115 may be disposed. The first insulating layer 115 may be configured as a single layer or a plurality of layers of silicon oxide (SiOₓ) or silicon nitride (SiNₓ). The first insulating layer 115 may be a gate insulating layer.

On a portion of the first insulating layer 115, the first electrode Cst1 of the storage capacitor Cst may be disposed. Also, in a partial area on the first insulating layer 115, at least one first light blocking layer BSM1 may be disposed. The first electrode Cst1 of the storage capacitor Cst and the first light blocking layer BSM1 may be formed of a single layer or multiple layers made of any one of molybdenum (Mo), aluminum (Al), chromium (Cr), gold (Au), titanium (Ti), nickel (Ni), neodymium (Nd), and copper (Cu), or an alloy of two or more thereof. The first light blocking layer BSM1 may be disposed to be overlapped with at least one of a plurality of oxide thin film transistors O-TFT.

On the first insulating layer 115, the first electrode Cst1 of the storage capacitor Cst, and the first light blocking layer BSM1, a second insulating layer 117 may be disposed. The second insulating layer 117 may cover the first electrode Cst1 of the storage capacitor Cst and the first light blocking layer BSM1. The second insulating layer 117 may include inorganic insulating material. The second insulating layer 117 may be an interlayer insulating layer.

On a portion of the second insulating layer 117, the second electrode Cst2 of the storage capacitor Cst may be disposed. The second electrode Cst2 of the storage capacitor Cst may be formed of a single layer or multiple layers made of any one of molybdenum (Mo), aluminum (Al), chromium (Cr), gold (Au), titanium (Ti), nickel (Ni), neodymium (Nd), and copper (Cu), or an alloy of two or more thereof. The second electrode Cst2 of the storage capacitor Cst may be disposed to be overlapped with the first electrode Cst1 to form the storage capacitor Cst.

On the second insulating layer 117 and the second electrode Cst2 of the storage capacitor Cst, a third buffer layer 118 may be disposed. The third buffer layer 118 may include an inorganic insulating layer including silicon oxide (SiOₓ) or silicon nitride (SiNₓ).

On a portion of the third buffer layer 118, a second light blocking layer BSM2 may be disposed. The second light blocking layer BSM2 may be formed of a single layer or multiple layers made of any one of molybdenum (Mo), aluminum (Al), chromium (Cr), gold (Au), titanium (Ti), nickel (Ni), neodymium (Nd), and copper (Cu), or an alloy of two or more thereof. The second light blocking layer BSM2 may be disposed to be overlapped with the oxide thin film transistor O-TFT used as a driving transistor of a pixel circuit.

On the third buffer layer 118 and the second light blocking layer BSM2, a first protective layer 119 may be disposed. The first protective layer 119 may include an inorganic insulating layer including silicon oxide (SiOₓ) or silicon nitride (SiNₓ). The first protective layer 119 may be a first passivation layer. On the first protective layer 119, at least two or more oxide thin film transistors O-TFT may be disposed.

The oxide thin film transistor O-TFT may include a semiconductor layer O-ACT, a gate electrode O-GAT, and a first source and drain electrode SD1. The oxide thin film transistor O-TFT may be a driving transistor or a switching transistor.

The semiconductor layer O-ACT of the oxide thin film transistor O-TFT may, for example, include an oxide semiconductor material, such as indium-gallium-zinc-oxide (IGZO) or indium-zinc-oxide (IZO).

The semiconductor layer O-ACT may include a channel region, a source region, and a drain region. A region of the semiconductor layer O-ACT, which is overlapped with the gate electrode O-GAT, may be a channel region. For example, a region of the semiconductor layer O-ACT, which is overlapped with the gate electrode O-GAT in the up and down direction, may be a channel region. The source region and the drain region may be disposed on both sides of the channel region, respectively.

The third insulating layer 121 may be disposed between the semiconductor layer O-ACT and the gate electrode O-GAT. The third insulating layer 121 may be configured with a single layer or a plurality of layers of silicon oxide (SiOₓ) or silicon nitride (SiNₓ).

The gate electrode O-GAT may be disposed on the third insulating layer 121. The gate electrode O-GAT may be formed of a single layer or multiple layers made of any one of molybdenum (Mo), aluminum (Al), chromium (Cr), gold (Au), titanium (Ti), nickel (Ni), neodymium (Nd), and copper (Cu), or an alloy of two or more thereof.

On the gate electrode O-GAT, a fourth insulating layer 123 may be disposed. The fourth insulating layer 123 may cover the gate electrode O-GAT. The fourth insulating layer 123 may include inorganic insulating material. For example, the fourth insulating layer 123 may include silicon oxide (SiOₓ) or silicon nitride (SiNₓ). The fourth insulating layer 123 may be an interlayer insulating layer.

On the fourth insulating layer 123, at least one or more first source and drain electrodes SD1 may be disposed. At least one first source and drain electrode SD1 may be electrically connected with the source and drain regions, respectively, of the semiconductor layer O-ACT through contact holes penetrating the fourth insulating layer 123 and the third insulating layer 121. Additionally, another first source and drain electrode SD1 may be electrically connected to the second electrode Cst2 of the storage capacitor Cst through a contact hole penetrating the fourth insulating layer 123, the third insulating layer 121, the first protective layer 119, and the third buffer layer 118. The first source and drain electrode SD1 may be formed of multiple layers made of any one of molybdenum (Mo), aluminum (Al), chromium (Cr), gold (Au), titanium (Ti), nickel (Ni), neodymium (Nd), and copper (Cu), or an alloy of two or more thereof.

The second light blocking layer BSM2 disposed between the third buffer layer 118 and the semiconductor layer O-ACT may block external light incident toward the semiconductor layer O-ACT. Additionally, the first light blocking layer BSM1 disposed between the first insulating layer 115 and the semiconductor layer O-ACT of another thin film transistor may also serve to block external light incident toward the semiconductor layer O-ACT.

On the fourth insulating layer 123 and the first source and drain electrodes SD1, a first planarization layer 124 may be disposed.

The first planarization layer 124 may planarize step differences generated by the underlying circuit elements including the oxide thin film transistor O-TFT. The first planarization layer 124 may include organic insulating material, such as acrylic resin, epoxy resin, phenolic resin, polyamide resin, or polyimide resin.

On a portion of the first planarization layer 124, a second source and drain electrode SD2 may be disposed. The second source and drain electrode SD2 may be electrically connected with the first source and drain electrode SD1 through a contact hole penetrating the first planarization layer 124.

On the second source and drain electrode SD2 and the first planarization layer 124, a second planarization layer 125 may be disposed, and on the second planarization layer 125, a third planarization layer 126 may be disposed.

On at least one portion of the third planarization layer 126, the anode electrode 131 may be disposed. The anode electrode 131 may be electrically connected with the second source and drain electrode SD2 through a contact hole 129 penetrating the second planarization layer 125 and the third planarization layer 126.

On the third planarization layer 126, the light-emitting array part 130 may be disposed. The light-emitting array part 130 may include first and second banks 132 and 136, and a light-emitting element. The light-emitting element may include the anode electrode 131, the light-emitting layer 134, and the cathode electrode 135.

The anode electrode 131 may be disposed on the third planarization layer 126. The anode electrode 131 may be electrically connected with the second source and drain electrode SD2 through the contact hole 129. Thereby, the anode electrode 131 may be electrically connected with the first source and drain electrode SD1 of the oxide thin film transistor O-TFT.

The anode electrode 131 may include metal oxide such as indium tin oxide (ITO) or indium zinc oxide (IZO). Alternatively, the anode electrode 131 may include a single-layer or multilayer structure including a reflective metal film formed of silver (Ag), aluminum (Al), gold (Au), nickel (Ni), chromium (Cr), and a compound thererof.

On the third planarization layer 126, the first and second banks 132 and 136 may be disposed. The first bank 132 may be formed to cover an edge of the anode electrode 131. Additionally, the first bank 132 may prevent lights of different colors of adjacent pixels being output while being mixed with each other.

The first bank 132 may include an organic insulating film of polyimide, epoxy, or the like. For example, the first bank 132 may be made of a material including a black pigment or the like, or an organic material such as a benzocyclobutene resin, an epoxy resin, a polyimide resin, an acrylic resin, or a photosensitive polymer.

The second bank 136 may include an organic insulating layer of polyimide, epoxy, or the like, and may be formed to be transparent unlike the first bank 132.

On the first bank 132, a spacer 137 may be further disposed, and the spacer 137 may be formed only on one of a plurality of pixels. The spacer 137 may protect the light-emitting layer 134 by preventing the light-emitting layer 134 from being directly impacted by an external impact.

In a portion of the third planarization layer 126, which is overlapped with the first and second banks 132 and 136, a trench may be formed. In the portion where the trench is formed, the first bank 132 may be disposed so that the first bank 132 may be disposed on the upper surface of the second planarization layer 125.

In a trench region 138 of the third planarization layer 126, the first and second banks 132 and 136 may have a concave portion formed therein. Thereby, the cathode electrode 135 disposed on the upper portion of the second bank 136 may be broken off in the concave portion. The cathode electrode 135 may be formed very thin on the entire surface of the panel. If the cathode electrode 135 is formed on the entire surface of the panel, a phenomenon in which leakage current of the cathode continues to accumulate may occur. Because of this, the bank concave portion is formed in the first and second banks 132 and 136, so that the trench region 138 may be disposed where the cathode electrode 135 is broken off, thereby enabling the prevention of leakage current accumulation.

On the anode electrode 131, the light-emitting layer 134 may be disposed. In an example, the light-emitting layer 134 may include organic material that emits light of different color for each pixel. For example, the light-emitting layer 134 may emit light of one color among red, green, blue, and white. In another example, the light-emitting layer 134 may be made of organic material that emits blue light and white light, and display one color among red, green, or blue by a color filter disposed in a light-emitting area.

The light-emitting layer 134 may include a stack structure including a hole transporting layer (HTL), an emission material layer (EML), an electron transporting layer (ETL), a hole blocking layer (HBL), a hole injection layer (HIL), an electron blocking layer (EBL), and an electron injecting layer (EIL).

FIG. 5 is a plan view illustrating a first area ZA1 in the display panel of FIG. 2.

Referring to FIG. 5, a plurality of pixels are disposed in the active area AA, and each pixel includes a circuit area and light-emitting areas EA_R, EA_G, and EA_B. In the circuit region, a driving transistor, switch transistors, a storage capacitor, data lines DL, and gate lines GL may be disposed. The light-emitting area EA_R represents the light-emitting area of the red pixel; the light-emitting area EA_G represents the light-emitting area of the green pixel; and the light-emitting area EA_B represents the light-emitting area of the blue pixel.

A plurality of power lines may be disposed in the active area AA. For example, the plurality of power lines may include a high-potential power line VDDL that supplies a high-potential driving voltage to a pixel, a low-potential power line VSSL that supplies a low-potential driving voltage to a pixel, a reset power line VARL that supplies a reset voltage to a pixel, and a reference power line VREFL that supplies a reference voltage to a pixel. Among the power lines, the low-potential power line VSSL may be formed to have the greatest width, and the high-potential power line VDDL may be formed to have the second greatest width. The reset power line VARL and the reference power line VREFL may formed to have the same width, and may be formed to have a width less than that of the high potential power line VDDL.

Additionally, in the active area AA, a plurality of data lines DL supplying a data voltage to a pixel circuit and a plurality of gate lines GL supplying a scan signal to a pixel circuit may be disposed. Here, the plurality of gate lines GLs may extend from the GIP area of the non-active area NA to the pixel circuit of the active area AA. Additionally, in the active area AA, the sub-data line DLa extending from the data line DL to the ESD area may be disposed.

The non-active area NA is divided into an ESD area and a GIP area. In the ESD area, the ESD circuit may be disposed, and in the GIP area, the GIP circuit may be disposed. The ESD circuit may be electrically connected with the data line DL of the active area AA through the sub-data line DLa. The GIP circuit may be electrically connected with the pixel circuit of the active area AA through the gate line GL. Additionally, in the ESD area, the first voltage line VGHL supplying the gate high voltage VGH and the second voltage line VGLL supplying the gate low voltage VGL may be disposed. The ESD circuit may include at least one thin film transistor electrically connected to at least one of the sub-data line DLa, the first voltage line VGHL, and the second voltage line VGLL.

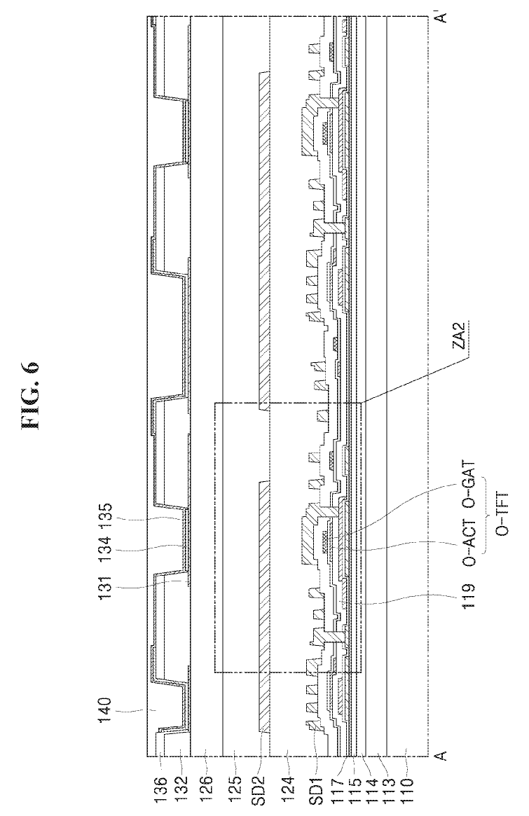

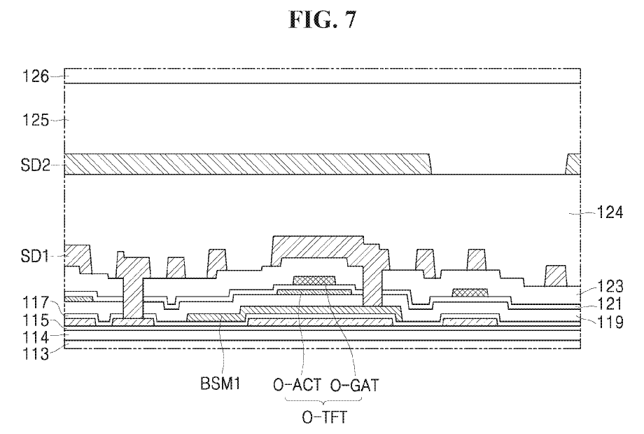

FIG. 6 is a cross-sectional view taken along the cutting line A-A′ located in the active area AA of FIG. 5. FIG. 7 is an enlarged cross-sectional view of the second area ZA2 of FIG. 6. In describing the illustrated embodiment, descriptions of components which are the same as or corresponding to those of the previous embodiments will be omitted.

Referring to FIGS. 6 and 7, a plurality of pixels are disposed in the active area AA, and the plurality of pixels include at least one oxide thin film transistor O-TFT.

The oxide thin film transistor O-TFT may include a semiconductor layer O-ACT, a gate electrode O-GAT, and a first source and drain electrode SD1. The oxide thin film transistor O-TFT may be a driving transistor or a switching transistor.

The semiconductor layer O-ACT of the oxide thin film transistor O-TFT may, for example, include an oxide semiconductor material such as indium-gallium-zinc-oxide (IGZO) or indium-zinc-oxide (IZO).

The semiconductor layer O-ACT may include a channel region, and a source region, and a drain region. A region of the semiconductor layer O-ACT, which is overlapped with the gate electrode O-GAT, may be a channel region. For example, a region of the semiconductor layer O-ACT, which is overlapped with the gate electrode O-GAT in the up and down direction, may be a channel region. The source region and drain region of the semiconductor layer O-ACT may be disposed on both sides of the channel region, respectively.

As described above, all thin film transistors provided in the active area AA may be oxide thin film transistors O-TFT to which oxide is applied. This active area AA may be defined as a non-crystallized area to which no ELA process is applied.

On the cathode electrode 135 of the light-emitting array part 130, the encapsulation layer 140 may be disposed. For example, the encapsulation layer 140 may include a multilayer structure. The encapsulation layer 140 may be disposed on the cathode electrode 135. The encapsulation layer 140 may include inorganic insulating material. For example, the encapsulation layer 140 may include at least one or more inorganic insulating material among silicon nitride (SiNₓ), silicon oxide (SiOₓ), and silicon oxynitride (SiON). The encapsulation layer 140 may prevent foreign substances from penetrating into the light-emitting element. The encapsulation layer 140 may include organic insulating material. For example, the encapsulation layer 140 may include at least one or more of epoxy, polyimide, polyethylene, and acrylate.

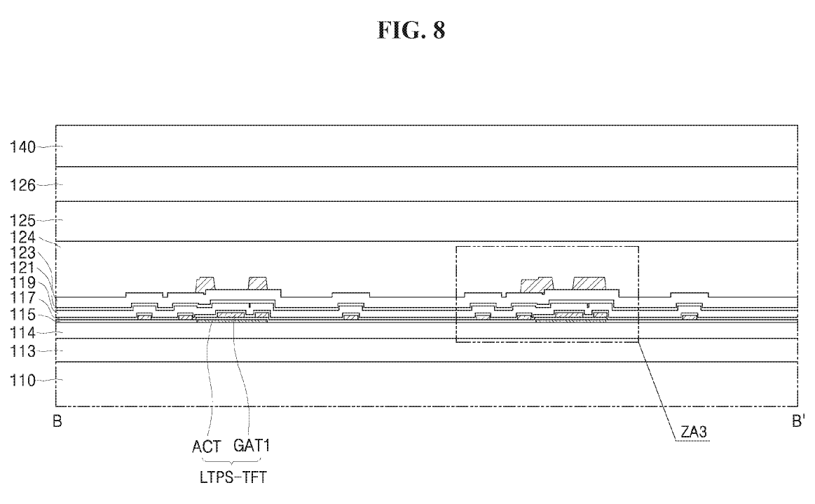

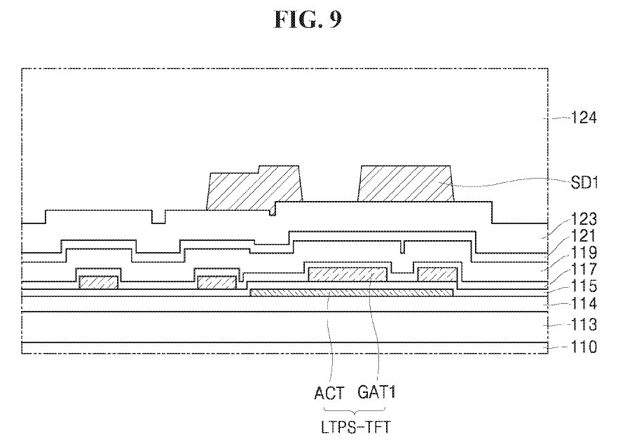

FIG. 8 is a cross-sectional view taken along line B-B′ in FIG. 5. FIG. 9 is an enlarged cross-sectional view of the third area ZA3 of FIG. 8. In describing the present embodiment, descriptions of components which are the same as or corresponding to those of the previous embodiments will be omitted.

Referring to FIGS. 8 and 9, the ESD circuit may be disposed in the ESD area of the non-active area NA. The ESD circuit may include at least one polycrystalline thin film transistor LTPS-TFT to which the LTPS has been applied.

The first buffer layer 113 may be disposed on the substrate 110. The first buffer layer 113, which serves to block the penetration of moisture or the like from the outside, may employ silicon oxide films or the like stacked in multiple layers. On the first buffer layer 113, the second buffer layer 114 may be further disposed to protect the element from the moisture permeation. The first buffer layer 113 and the second buffer layer 114 may include an inorganic insulating layer including silicon oxide (SiOₓ) or silicon nitride (SiNₓ).

The polycrystalline thin film transistor LTPS-TFT may be disposed on the second buffer layer 114. The polycrystalline thin film transistor LTPS-TFT may use a polycrystalline semiconductor as an active layer. The polycrystalline thin film transistor LTPS-TFT may include a polycrystalline active layer ACT including a channel region through which electrons or holes move, and a gate electrode GAT1, with a source region and a drain region disposed on both sides of the channel region in the polycrystalline active layer ACT, respectively. The source and drain regions may be regions which have been made to conduct by doping an intrinsic polycrystalline semiconductor material with group-5 or group-3 impurity ions, for example, phosphorus (P) or boron (B) to a predetermined concentration. The channel region, which maintains the intrinsic state of the polycrystalline semiconductor material, may provide a path through which electrons or holes move.

The polycrystalline thin film transistor LTPS-TFT includes the gate electrode GAT1 overlapped with the channel region of the polycrystalline active layer ACT. Between the gate electrode GAT1 and the polycrystalline active layer ACT, the first insulating layer 115 is disposed. The first insulating layer 115 may use an inorganic layer, such as a silicon oxide (SiO₂) film, a silicon nitride (SiNₓ) or the like, by stacking it in a single layer or in multiple layers.

The gate electrodes GAT1 of a plurality of polycrystalline thin film transistors LTPS-TFT of the ESD circuit and the GIP circuit in the non-active area NA may be formed on the same layer as the first electrode Cst1 of the storage capacitor Cst.

In an embodiment of the invention, the polycrystalline thin film transistor LTPS-TFT may be formed in a top gate structure in which the gate electrode GAT1 is positioned in the upper side of the polycrystalline active layer ACT. The gate electrode GAT1 is made of metallic material. For example, the gate electrode GAT1 may be a single layer or multiple layers made of any one of molybdenum (Mo), aluminum (Al), chromium (Cr), gold (Au), titanium (Ti), nickel (Ni), neodymium (Nd), and copper (Cu), or an alloy of two or more thereof.

As described above, every thin film transistor disposed in the ESD area of the non-active area NA may be formed as a polycrystalline thin film transistor LTPS-TFT. This non-active area NA may be manufactured by applying an ELA process, and may be defined as an ELA crystallized area.

According to an embodiment of the invention, the display apparatus may employ oxide thin film transistors to a plurality of pixels in the active area, and employ LTPS thin film transistors to the ESD circuit and the GIP circuits in the non-active area.

According to an embodiment of the invention, the display apparatus may realize low power consumption and maintain the characteristics of LTPS with robust reliability, by disposing pixels, to which oxide thin film transistors have been applied, in an active area, and by disposing an ESD circuit, to which LTPS thin film transistors have been applied, in a non-active area in which GIP circuits are disposed.

According to an embodiment of the invention, the display apparatus may realize low power consumption and drive pixels accurately at a high speed by applying the oxide thin film transistors to the active area in which multiple pixels are disposed, and by applying the LTPS thin film transistors to the non-active area in which the ESD circuit and the GIP circuits are disposed.

When manufacturing a large-area display panel, the display apparatus according to an embodiment of the invention may has an effect of maintaining the ELA process to a partial area rather than the entire area by implementing an ESD circuit and a GIP circuit using LTPS thin film transistors on both sides of the active area. In this manner, the number of process equipment may be reduced, process tact time may be shortened, and production capacity and production efficiency may be improved.

Also, the display apparatus according to an embodiment of the invention has an effect of discharging static electricity introduced to the data line by disposing the sub-data line connecting the ESD circuit in the non-active area from the data line in the active area.

Also, since the display apparatus according to an embodiment of the invention may quickly discharge the introduced static electricity through the ESD circuit to which the LTPS thin film transistor has been applied, it has an effect of protecting the pixel circuit from static electricity.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display apparatus comprising:
an active area in which a plurality of pixels are disposed; and
non-active areas arranged on both sides of the active area in a horizontal direction,
wherein:
in each of the non-active areas, an electro-static discharge (ESD) circuit and a gate-in-panel (GIP) circuit are disposed; and
in the active area, the pixels include a thin film transistor to which oxide has been applied, and semiconductor elements to which low temperature polycrystalline silicon (LTPS) has been applied are disposed.

2. The display apparatus of claim 1, wherein the non-active area is an area to which an excimer laser annealing (ELA) process for converting amorphous silicon (a-Si) into polycrystalline silicon (poly-Si) has been applied, and the active area is an area to which no ELA process has been applied.

3. The display apparatus of claim 1, wherein the ESD circuit disposed in the non-active area is electrically connected with a data line in the active area through a sub-data line.

4. The display apparatus of claim 3, wherein the sub-data line extends in the horizontal direction from the data line in the active area to the ESD circuit disposed in the non-active area.

5. The display apparatus of claim 3, wherein, in the non-active area in which the ESD circuit is disposed, a first voltage line transmitting a gate high voltage and a second voltage line transmitting a gate low voltage are further disposed.

6. The display apparatus of claim 5, wherein the ESD circuit includes:
a first thin film transistor having a first electrode electrically connected to the sub-data line, a second electrode electrically connected to the first voltage line, and a gate electrode electrically connected to the first voltage line; and
a second thin film transistor having a first electrode electrically connected to the sub-data line, a second electrode electrically connected to the second voltage line, and a gate electrode electrically connected to the sub-data line.

7. The display apparatus of claim 6, wherein the first thin film transistor and the second thin film transistor comprise p-type LTPS-thin film transistors.

8. The display apparatus of claim 1, wherein the pixels include a driving transistor and at least one switch transistor, and both the driving transistor and the at least one switch transistor are oxide thin film transistors.

9. The display apparatus of claim 1, wherein the GIP circuit includes at least one LTPS-thin film transistor.

10. The display apparatus of claim 1, wherein the GIP circuit disposed in the non-active area is electrically connected with the pixels disposed in the active area through gate lines.

11. A large-area display panel comprising a large-area substrate on which a plurality of display panels are arranged in a matrix,
wherein:
each of the plurality of display panels includes:
an active area in which a plurality of pixels are disposed; and
non-active areas arranged on both sides of the active area in a horizontal direction;
in each of the non-active areas, an electro-static discharge (ESD) circuit and a gate-in-panel (GIP) circuit are disposed; and
in the active area, the plurality of pixels include a thin film transistor to which oxide has been applied, and the ESD circuit and the GIP circuit include a thin film transistor to which low temperature poly silicon (LTPS) has been applied.

12. The large-area display panel of claim 11, wherein the non-active area is an excimer laser annealing (ELA) crystallized area to which an ELA process has been applied, and the active area is a non-crystallized area to which no ELA process has been applied.

13. The large-area display panel of claim 11, wherein:
a data line transmitting a data voltage is disposed in the active area; and
the ESD circuit disposed in the non-active area is electrically connected with the data line in the active area through a sub-data line.

14. The large-area display panel of claim 13, wherein the sub-data line extends in the horizontal direction from the data line in the active area to the ESD circuit disposed in the non-active area.

15. The large-area display panel of claim 13, wherein, in the non-active area in which the ESD circuit is disposed, a first voltage line transmitting a gate high voltage, and a second voltage line transmitting a gate low voltage are disposed.

16. The large-area display panel of claim 15, wherein the ESD circuit includes:
a first thin film transistor having a first electrode electrically connected to the sub-data line, a second electrode electrically connected to the first voltage line, and a gate electrode electrically connected to the first voltage line; and
a second thin film transistor having a first electrode electrically connected to the sub-data line, a second electrode electrically connected to the second voltage line, and a gate electrode electrically connected to the sub-data line.

17. The large-area display panel of claim 16, wherein the first thin film transistor and the second thin film transistor comprise p-type LTPS-thin film transistors.

18. The large-area display panel of claim 11, wherein:
the pixels in the active area include a driving transistor and at least one switch transistor, and both the driving transistor and the at least one switch transistor are oxide thin film transistors; and
the ESD circuit and the GIP circuit in the non-active area include at least one or more transistors, and all of the at least one or more transistors are LTPS thin film transistors.

19. The large-area display panel of claim 11, wherein:
a gate line transmitting a gate signal is disposed in the active area; and
the GIP circuit in the non-active area is electrically connected with the pixels in the active area through the gate line.
